(19) United States
(12) Patent Application Publication
(10) Pub. No.: US 2014/0167251 A1
(43) Pub. Date: Jun. 19, 2014

(54) SEMICONDUCTOR DEVICE, SEMICONDUCTOR MODULE, AND MANUFACTURING METHOD FOR SEMICONDUCTOR DEVICE

(71) Applicant: Kabushiki Kaisha Toshiba, Minato-ku (JP)

(72) Inventor: Yoshihisa IWATA, Kanagawa (JP)

(73) Assignee: Kabushiki Kaisha Toshiba, Minato-ku (JP)

(21) Appl. No.: 14/023,927

(22) Filed: Sep. 11, 2013

(30) Foreign Application Priority Data
Dec. 17, 2012 (JP) 2012-274725

(51) Int. Cl. H01L 23/482; H01L 21/768; H01L 21/822; H01L 23/50

(52) U.S. Cl. CPC H01L 23/4822; H01L 23/50; H01L 21/768; H01L 21/822
USPC 257/735; 438/461

(57) ABSTRACT

According to an embodiment, a semiconductor device includes a silicon substrate, an insulation film, and a plurality of chip-side connection terminals. The silicon substrate is internally provided with a first wire layer. The insulation film is stacked on a first surface of surfaces of the silicon substrate, the first surface being approximately parallel to the first wire layer. The chip-side connection terminals are electrically connected to the wire layer. Moreover, the chip-side connection terminals are exposed on a second surface side, the second surface being continuous from the first surface in an approximately perpendicular manner.

### CROSS-REFERENCE TO RELATED APPLICATIONS

This application is based upon and claims the benefit of priority from Japanese Patent Application No. 2012-274725, filed on Dec. 17, 2012; the entire contents of which are incorporated herein by reference.

### FIELD

Embodiments described herein relate generally to a semiconductor device, a semiconductor module, and a manufacturing method for a semiconductor device.

### BACKGROUND

Conventionally, a semiconductor module having a plurality of semiconductor chips (semiconductor devices) stacked and mounted on a printed board (wiring board) has been used. In such a semiconductor module, wire bonding with the use of a metal wire may cause electric connection between a wire layer of the printed board and a wire layer of the semiconductor chip, or between the wire layers of the semiconductor chips. Moreover, when a via hole is formed through the semiconductor chip and the via hole is filled with metal, electric connection may be caused between a wire layer of the printed board and a wire layer of the semiconductor chip, or between the wire layers of the semiconductor chips.

In the wire bonding with the use of the metal wire, the metal wire may vary in length. The variation in length of the metal wire may lead to variation in signal transmission performance. Further, when the via hole is filled with metal, a parasitic capacitance may be formed between the metal in the via hole and the surrounding silicon substrate, thereby deteriorating the signal transmission performance.

In view of this, a semiconductor device in which deterioration in signal transmission performance can be suppressed even though plural semiconductor devices are stacked and mounted on a substrate, and a semiconductor module including the semiconductor device have been desired.

### BRIEF DESCRIPTION OF THE DRAWINGS

FIG. 1 is a perspective view of a schematic structure of a semiconductor device according to a first embodiment;

FIG. 2 is a sectional view seen along an arrow X illustrated in FIG. 1;

FIG. 3 is a perspective view of a schematic structure of a semiconductor device according to a modified example of the first embodiment;

FIG. 4 is a sectional view seen along an arrow Y illustrated in FIG. 3;

FIG. 5A is a diagram depicting a sectional structure of a semiconductor module including a semiconductor device according to this embodiment;

FIG. 5B is a diagram depicting another example of the sectional structure of the semiconductor module;

FIG. 5C is a diagram depicting another example of the sectional structure of the semiconductor module;

FIG. 6A is a diagram of a printed board seen from a mount surface side;

FIG. 6B is a diagram depicting wires in a board, which are provided for a first layer below surface electrodes;

FIG. 6C is a diagram depicting wires in the board, which are provided for a second layer below the first layer;

FIG. 6D is a diagram depicting wires in the board, which are provided for a third layer below the second layer;

FIG. 6E is a diagram depicting wires in the board, which are provided for a fourth layer below the third layer;

FIG. 6F is a diagram depicting ball electrodes provided for a back surface of the mount surface;

FIG. 6G is a diagram of the printed board seen from the mount surface side, depicting another example of the surface electrodes;

FIG. 7 is a diagram depicting an example of the semiconductor device mounted on the printed board, which is seen from a second surface side;

FIG. 8 is a diagram depicting another example of the semiconductor device mounted on the printed board, which is seen from the second surface side;

FIG. 9A is a schematic diagram depicting an example of assigning functions to chip-side connection terminals;

FIG. 9B is a schematic diagram depicting another example of assigning the functions to the chip-side connection terminals;

FIG. 10 is a plan view of a semiconductor wafer before the semiconductor devices are divided into chips;

FIG. 11A is a sectional view taken along an arrow A-A illustrated in FIG. 10, for describing a procedure for manufacturing the semiconductor device;

FIG. 11B is a sectional view taken along an arrow B-B illustrated in FIG. 10, for describing the procedure for manufacturing the semiconductor device;

FIG. 12A is a sectional view taken along the arrow A-A illustrated in FIG. 10, for describing the procedure for manufacturing the semiconductor device;

FIG. 12B is a diagram for describing the procedure for manufacturing the semiconductor device and is a sectional view taken along line B-B illustrated in FIG. 10;

FIG. 13A is a sectional view taken along the arrow A-A illustrated in FIG. 10, for describing the procedure for manufacturing the semiconductor device;

FIG. 13B is a sectional view taken along the arrow B-B illustrated in FIG. 10, for describing the procedure for manufacturing the semiconductor device;

FIG. 14A is a sectional view taken along the arrow A-A illustrated in FIG. 10, for describing the procedure for manufacturing the semiconductor device;

FIG. 14B is a sectional view taken along the arrow B-B illustrated in FIG. 10, for describing the procedure for manufacturing the semiconductor device;

FIG. 15 is a sectional view for describing another example of the procedure for manufacturing the semiconductor device;

FIG. 16 is a sectional view for describing the other example of the procedure for manufacturing the semiconductor device;

FIG. 17 is a sectional view for describing the other example of the procedure for manufacturing the semiconductor device;

FIG. 18 is a sectional view for describing the other example of the procedure for manufacturing the semiconductor device;

FIG. 19 is a sectional view for describing the other example of the procedure for manufacturing the semiconductor device;

FIG. 20 is a sectional view for describing the other example of the procedure for manufacturing the semiconductor device;

FIG. 21 is a sectional view for describing the other example of the procedure for manufacturing the semiconductor device;

FIG. 22 is a plan view of a semiconductor wafer in a state that test electrodes are formed;

FIG. 23 is a plan view of a semiconductor wafer in a state that test electrodes are formed;

FIG. 24 is a sectional view taken along an arrow C-C illustrated in FIG. 23;

FIG. 25 is a plan view of a semiconductor wafer;

FIG. 26A is a sectional view taken along an arrow D-D illustrated in FIG. 25;

FIG. 26B is a sectional view taken along an arrow E-E illustrated in FIG. 25;

FIG. 27A is a sectional view taken along the arrow D-D illustrated in FIG. 25;

FIG. 27B is a sectional view taken along the arrow E-E illustrated in FIG. 25;

FIG. 28A is a sectional view taken along the arrow D-D illustrated in FIG. 25;

FIG. 28B is a sectional view taken along the arrow E-E illustrated in FIG. 25;

FIG. 29A is a sectional view taken along the arrow D-D illustrated in FIG. 25;

FIG. 29B is a sectional view taken along the arrow E-E illustrated in FIG. 25;

FIG. 30A is a sectional view taken along the arrow D-D illustrated in FIG. 25;

FIG. 30B is a sectional view taken along the arrow E-E illustrated in FIG. 25;

FIG. 31 is a diagram depicting another configuration example of the semiconductor module;

FIG. 32 is a diagram in which a semiconductor device included in the semiconductor module of FIG. 31 is seen from the chip-side connection terminal side;

FIG. 33 is a diagram depicting another configuration example of semiconductor devices arranged side by side, which is seen from the chip-side connection terminal side; and

FIG. 34 is a diagram depicting another configuration example of semiconductor devices arranged side by side, which is seen from the chip-side connection terminal side.

### DETAILED DESCRIPTION

In general, according to one embodiment, a semiconductor device includes a silicon substrate, an insulation film, and a plurality of chip-side connection terminals. The silicon substrate is internally provided with a first wire layer. The insulation film is stacked on a first surface of surfaces of the silicon substrate, which is approximately parallel to the first wire layer. The plural chip-side connection terminals are electrically connected to wire layers. The plural chip-side connection terminals are exposed on a second surface side, the second surface being continuous from the first surface in an approximately perpendicular manner.

Exemplary embodiments of a semiconductor device, a semiconductor module, and a manufacturing method for a semiconductor device will be explained below in detail with reference to the accompanying drawings. The present invention is not limited to the following embodiments.

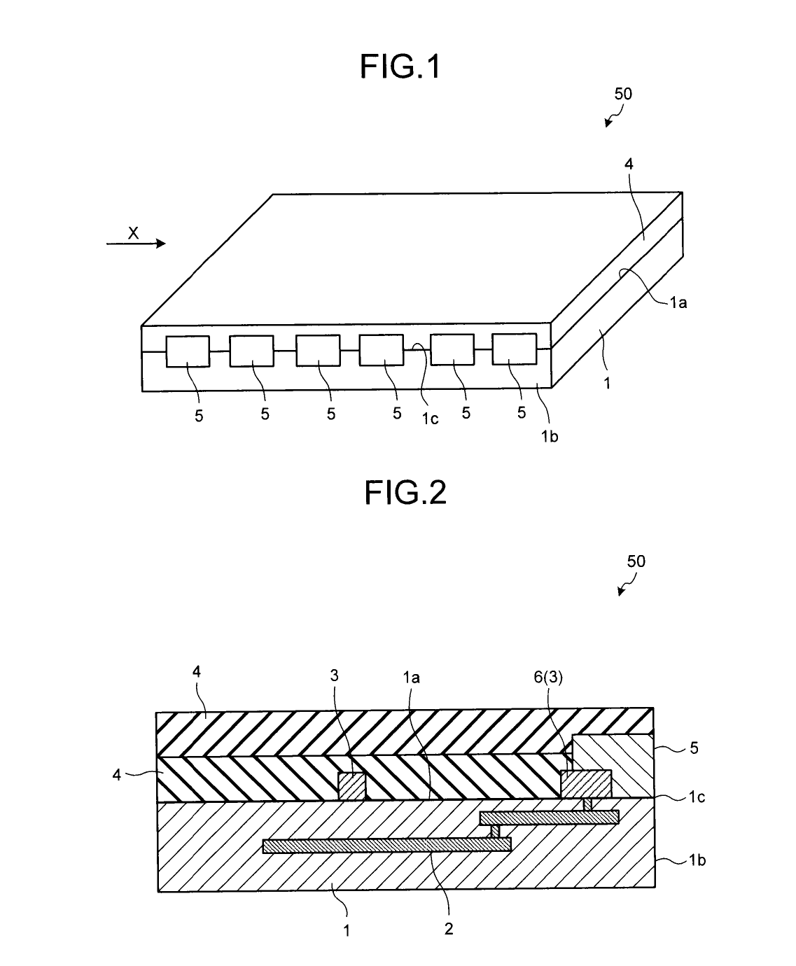

FIG. 1 is a perspective view depicting a schematic structure of a semiconductor device according to a first embodiment. FIG. 2 is a sectional view seen along an arrow X illustrated in FIG. 1. A semiconductor device 50 has a square shape as a plan shape and has a shape like a thin plate as a whole. As depicted in FIG. 2, the semiconductor device 50 includes a silicon substrate 1, an internal wire layer (first wire layer) 2, an external wire 3, an insulation layer (an insulation film) 4, and a chip-side connection terminal 5.

The internal wire layer 2 is a wire layer provided inside the silicon substrate 1. The external wire 3 is formed on a first surface 1a of surfaces of the silicon substrate 1, which is approximately parallel to the internal wire layer 2. The external wire 3 includes a pad electrode 6. The external wire 3 is electrically connected to the internal wire layer 2. The insulation layer 4 is stacked on the first surface 1a of the silicon substrate 1. The insulation layer 4 functions as a passivating film covering the first surface 1a of the silicon substrate 1 and the external wire 3.

The chip-side connection terminal 5 is a metal plating provided on the pad electrode 6. The chip-side connection terminal 5 is exposed from a second surface 1b of the surfaces of the silicon substrate 1, which is continuous from the first surface 1a in an approximately perpendicular manner. The semiconductor device 50 includes plural chip-side connection terminals 5. The plural chip-side connection terminals 5 are disposed side by side in approximately parallel to the side (boundary side 1c) of a boundary between the first surface 1a and the second surface 1b.

Each of the plural chip-side connection terminals 5 has a function assigned thereto. The plural chip-side connection terminals 5 function as, for example, a CE (Chip Enable) terminal, a WE (Write Enable) terminal, an OE (Output Enable) terminal, a VDD (power source potential) terminal, a VSS (ground potential) terminal, an ADD (address) terminal, and an I/O (Input/Output) terminal.

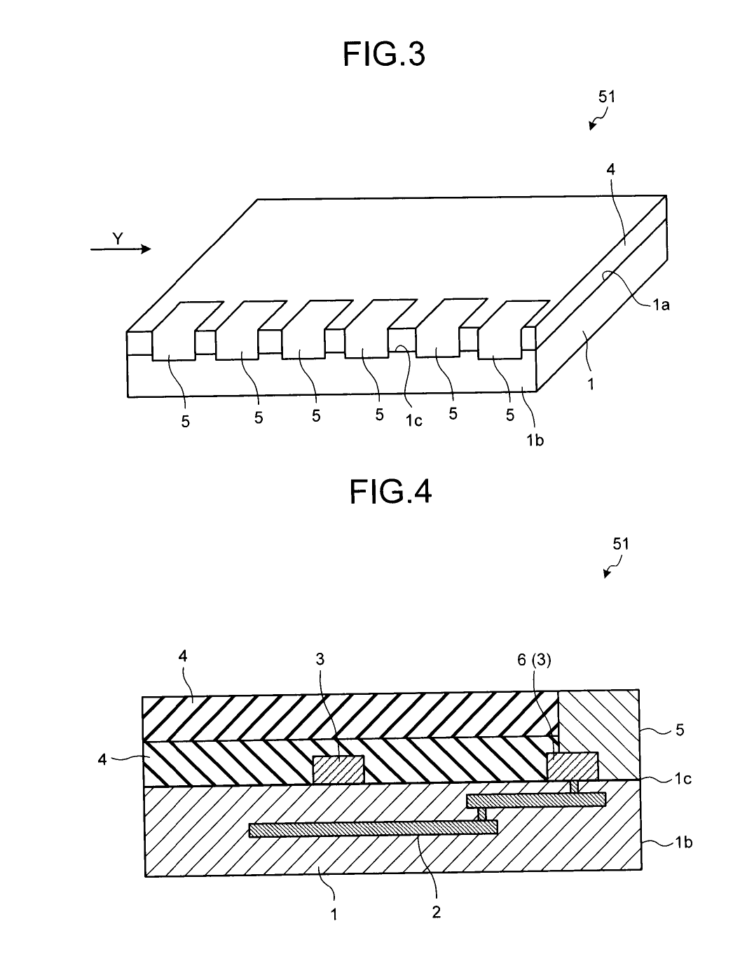

FIG. 3 is a perspective view depicting a schematic structure of a semiconductor device according to a modified example of the first embodiment. FIG. 4 is a sectional view seen along an arrow Y illustrated in FIG. 3. In the semiconductor device 50 illustrated in FIG. 1 and FIG. 2, the chip-side connection terminal 5 is exposed from the second surface 1b side only; however, in a semiconductor device 51 illustrated in FIG. 3 and FIG. 4, the chip-side connection terminal 5 is additionally exposed from the first surface 1a side.

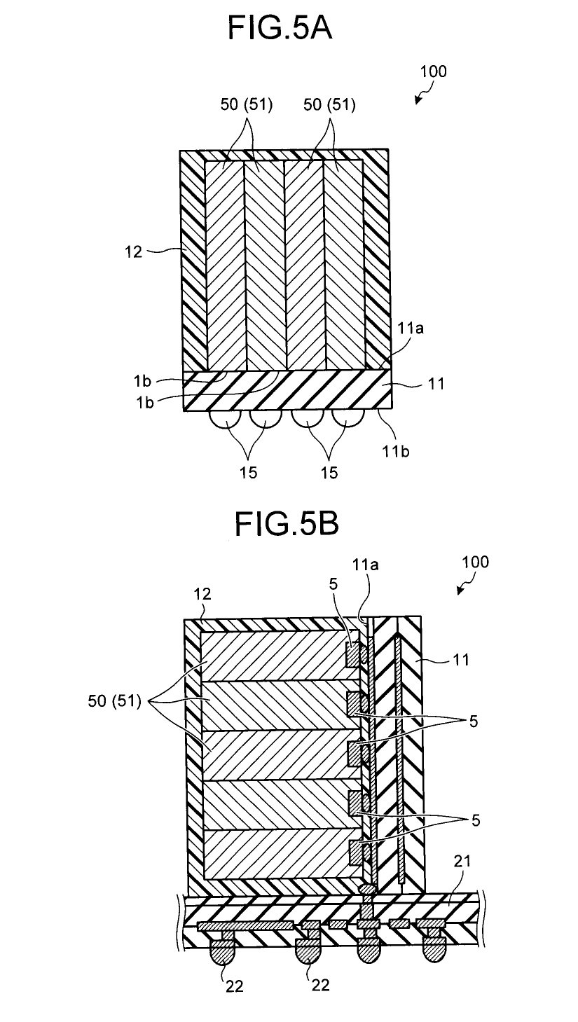

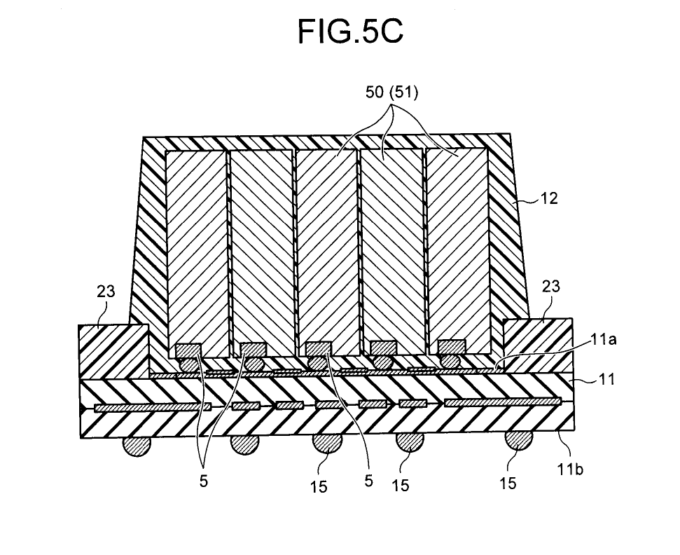

FIG. 5A is a diagram depicting a sectional structure of a semiconductor module including the semiconductor device according to this embodiment. A semiconductor module 100 has a plurality of semiconductor devices 50 (51) mounted on a mount surface 11a of a printed board (wiring board) 11, and has a mold part 12 provided to cover the mount surface 11a and the semiconductor devices 50 (51).

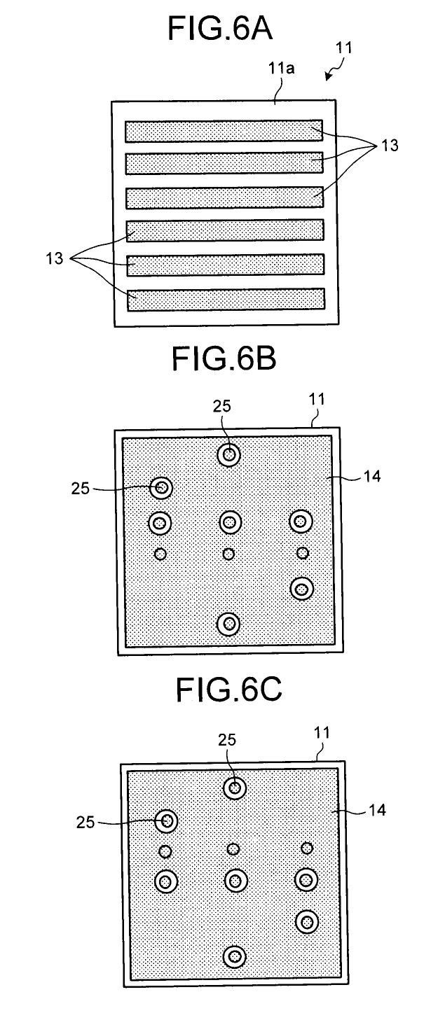

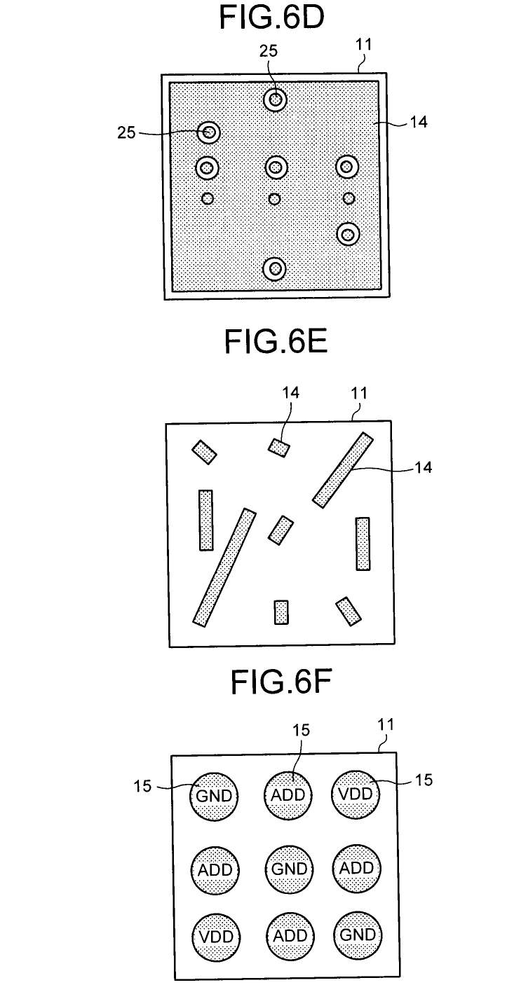

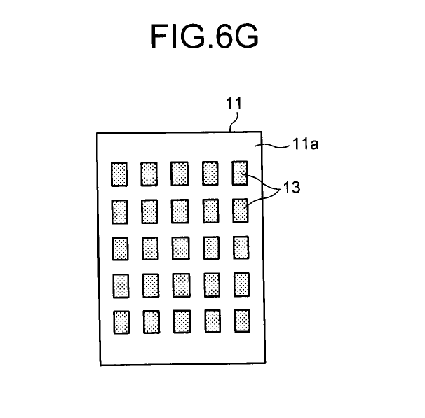

FIG. 6A is a diagram in which the printed board 11 is seen from the mount surface 11a side. The mount surface 11a of the printed board 11 is provided with a plurality of surface electrodes (substrate-side connection terminals) 13. The surface electrode 13 has a belt-like shape extending in approximately parallel to a direction where the semiconductor devices 50 (51) are arranged. When the semiconductor devices 50 (51) are mounted on the mount surface 11a with the second surface 1b side facing the mount surface 11a, the chip-side connection terminal 5 and the surface electrode 13 are electrically connected to each other. Note that a solder may be used for surely connecting the chip-side connection terminal 5 and the surface electrode 13 to each other.

Inside the printed board 11, wires in the board which are formed in approximately parallel to the surface electrodes 13 are stacked and four wires in the board are formed in this embodiment. Between the wires stacked in the board, an interlayer insulation film including a synthetic resin or the like is provided.

FIG. 6B is a diagram depicting the wires in the board provided for a first layer below the surface electrodes 13. FIG. 6C is a diagram depicting the wires in the board provided for a second layer below the first layer. FIG. 6D is a diagram depicting the wires in the board provided for a third layer below the second layer. FIG. 6E is a diagram depicting the wires in the board provided for a fourth layer below the third layer. FIG. 6F is a diagram depicting ball electrodes provided for a back surface 11b of the mount surface 11a.

As depicted in FIGS. 6A to 6F, the surface electrodes 13 provided for the mount surface 11a of the printed board 11 and the ball electrodes 15 provided for the back surface 11b of the printed board 11 are electrically connected to each other through wires 14 in the board or vias 25 provided between the layers.

Note that the wires 14 in the board provided for the first layer depicted in FIG. 6B and the third layer depicted in FIG. 6D each serve as a ground wire. The wire 14 in the board provided for the second layer serves as a VDD wire used for supplying a power source potential (VDD).

FIG. 6G is a diagram depicting another example of the surface electrodes 13, in which the printed board 11 is seen from the mount surface 11a side. As depicted in FIG. 6G, the surface electrodes 13 may be provided in an island shape for the mount surface 11a so as to be in contact with the chip-side connection terminals 5 of the semiconductor devices 50 (51). Alternatively, the belt-like surface electrodes 13 and the island-like surface electrodes 13 may be formed in combination.

FIG. 5B is a diagram depicting another example of the sectional structure of the semiconductor module 100. As depicted in FIG. 5B, the surface electrode 13 of the printed board 11 may be extended to the side surface and the printed board 11 may be mounted on a mount surface of another printed board (wiring board) 21. In this case, ball electrodes 22 are provided for the other printed board 21 side. Note that the mold part 12 is provided so as to cover the mount surface 11a and the semiconductor devices 50 (51).

FIG. 5C is a diagram depicting another example of the sectional structure of the semiconductor module 100. As depicted in FIG. 5C, a surrounding wall 23 may be provided around the semiconductor devices 50 (51) on the mount surface 11a of the printed board 11. The surrounding wall 23 can make it difficult for the semiconductor devices 50 (51) to collapse. The height of the surrounding wall 23 may be arbitrarily determined. For example, the height of the surrounding wall 23 may be determined to be similar to that of the semiconductor device 50 (51). Note that the mold part 12 is provided so as to cover the mount surface 11a and the semiconductor devices 50 (51).

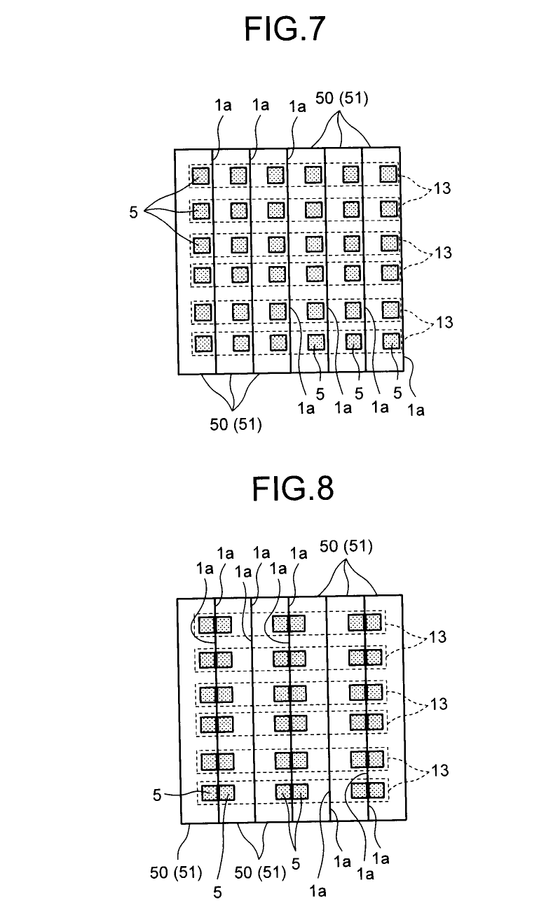

FIG. 7 is a diagram depicting an example of the semiconductor devices 50 (51) mounted on the printed board 11, in which the semiconductor devices 50 (51) are seen from the second surface 1b side. In FIG. 7, the surface electrodes 13 on the printed board 11 are illustrated with dashed lines. In the example depicted in FIG. 7, the semiconductor devices 50 (51) are arranged on the printed board 11 with the first surfaces 1a facing in the same direction.

When the semiconductor devices 50 (51) are arranged with the first surfaces 1a facing in the same direction as depicted in FIG. 7 and the assignment of the functions to the chip-side connection terminals 5 is the same in all the semiconductor devices 50 (51), the chip-side connection terminals 5 having the same functions can be brought into contact with the same surface electrode 13. Therefore, the chip-side connection terminals 5 having the same function can be brought into contact with the same surface electrode 3 by preparing one kind of semiconductor devices 50 (51) in which the assignment of the functions to the chip-side connection terminals 5 is the same.

FIG. 8 is a diagram depicting another example of the semiconductor devices 50 (51) mounted on the printed board 11, in which the semiconductor devices 50 (51) are seen from the second surface 1b side. In FIG. 8, the surface electrodes 13 on the printed board 11 are illustrated with dashed lines. In the example illustrated in FIG. 8, the semiconductor devices 50 (51) are arranged on the printed board 11 with the first surfaces 1a facing each other. The semiconductor devices 50 (51) are arranged adjacent to each other. Although not illustrated, spacer such as a silicon substrate may be held between the semiconductor devices 50 (51). Alternatively, an elastic body may be held between the semiconductor devices 50 (51) to relieve the stress. Further alternatively, a heat release body may be held between the semiconductor devices 50 (51) to improve the heat release property.

When the semiconductor devices 50 (51) are arranged with the first surfaces 1a facing each other as depicted in FIG. 8 and the assignment of the functions to the chip-side connection terminals 5 is symmetrical, the chip-side connection terminals 5 having the same function can be brought into contact with the same surface electrode 13. Therefore, the chip-side connection terminals 5 having the same function can be brought into contact with the same surface electrode 13 by preparing two kinds of semiconductor devices 50 (51) in which the assignment of the functions to the chip-side connection terminals 5 is symmetrical.

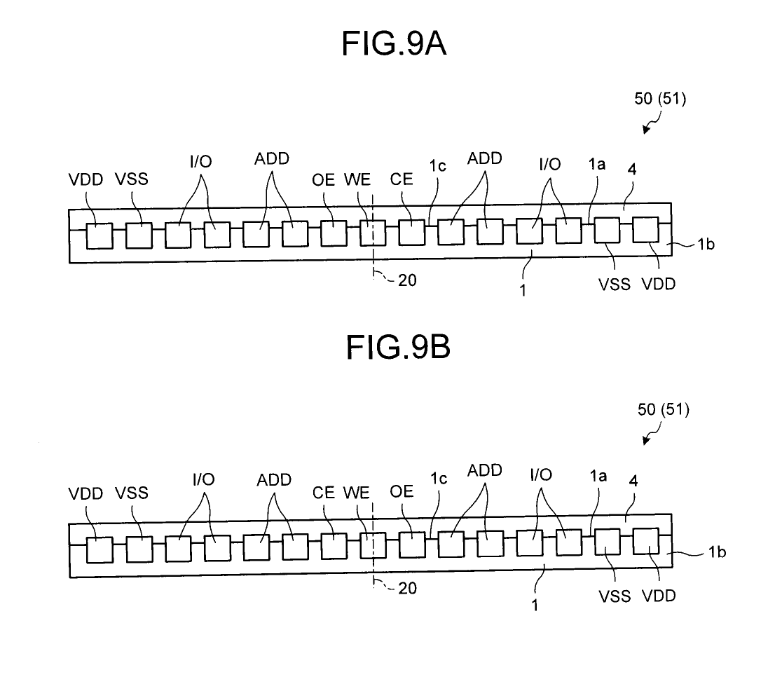

FIG. 9A is a schematic diagram depicting an example of the assignment of the functions to the chip-side connection terminals 5. FIG. 9B is a schematic diagram depicting another example of the assignment of the functions to the chip-side connection terminals 5. FIG. 9A and FIG. 9B each depict an example in which 15 chip-side connection terminals 5 are provided in one semiconductor device 50 (51). The chip-side connection terminals 5 include, as aforementioned, a CE (Chip Enable) terminal, a WE (Write Enable) terminal, an OE (Output Enable) terminal, an ADD (Address) terminal, a VDD (power source potential) terminal, a VSS (ground potential) terminal, and an I/O (Input/Output) terminal.

In this embodiment, the enable terminals (CE terminal, WE terminal, OE terminal) handling enable signals are disposed at a central part of the chip-side connection terminals 5 arranged side by side. Among the enable terminals, the WE terminal is disposed at the center and the CE terminal and the OE terminal are disposed to have the WE terminal interposed therebetween. In the example of FIG. 9A and the example of FIG. 9B, the positions of the CE terminal and the OE terminal, which have the WE terminal interposed therebetween, are symmetrical.

When the semiconductor devices 50 (51) are arranged with the first surfaces 1a facing each other as depicted in FIG. 8, the enable terminals having the same function face each other by preparing the two kinds of semiconductor devices 50 (51) of the example depicted in FIG. 9A and the example depicted in FIG. 9B. Therefore, the enable terminals having the same function can be brought into contact with the same surface electrode 13.

On both sides of the enable terminals, the same number of ADD terminals are arranged. The ADD terminals may face each other when the semiconductor devices 50 (51) are arranged with the first surfaces 1a facing each other. As long as the terminal is brought into contact with the surface electrode for the address signal, the terminal can function as the ADD terminal according to the address signal input from the surface electrode 13 even though the address number is not preset.

Therefore, if the ADD terminals are arranged symmetrically with the enable terminals interposed therebetween on both sides of the enable terminals, i.e., as long as the ADD terminals are arranged symmetrically about a central line 20 which is perpendicular to the first surface 1a through the boundary side 1c, the ADD terminals can be disposed to face each other by arranging the semiconductor devices 50 (51) with the first surfaces 1a facing each other. When the ADD terminals facing each other are brought into contact with the surface electrode 13 for the address signal, the ADD terminals can function as the ADD terminals according to the address signal. Therefore, there is no difference in arrangement of the ADD terminals between the example of FIG. 9A and in the example of FIG. 9B. The ADD terminals may alternatively be arranged so as to be symmetric about the central line 20 in the example of FIG. 9A and the example of FIG. 9B by setting the address number for each ADD terminal in advance. On both sides of the ADD terminals, the I/O terminals are arranged. The I/O terminals are disposed symmetrically about the central line 20 which is perpendicular to the first surface 1a through the boundary side 1c. Since the I/O terminals are disposed symmetrically on both sides of the enable terminals, the number of the I/O terminals is an even number.

On both sides of the I/O terminals, the VSS terminal and the VDD terminal are arranged as the power source terminals. The VSS terminal and the VDD terminal are disposed symmetrically about the central line 20 which is perpendicular to the first surface 1a through the boundary side 1c. In this embodiment, the VSS terminal is disposed on the inside as compared with the VDD terminal; however, any of the VSS terminal and the VDD terminal may be disposed on the inside as long as the terminals are disposed symmetrically on both sides of the enable terminals. The number of each of the VSS terminal and the VDD terminal is not limited to one. Since the VSS terminal and the VDD terminal are disposed symmetrically on both sides of the enable terminals, the number thereof is an even number. In a manner similar to the ADD terminal, there is no difference in arrangement of the VSS terminal and the VDD terminal between the example of FIG. 9A and the example of FIG. 9B.

As thus described, in the case of arranging the semiconductor devices 50 (51) so that the first surfaces 1a face in the same direction, one of the example of FIG. 9A and the example of FIG. 9B may be employed as the semiconductor devices 50 (51); in the case of arranging the semiconductor devices 50 (51) so that the first surfaces 1a face each other, both the example of FIG. 9A and the example of FIG. 9B may be employed as the semiconductor devices 50 (51).

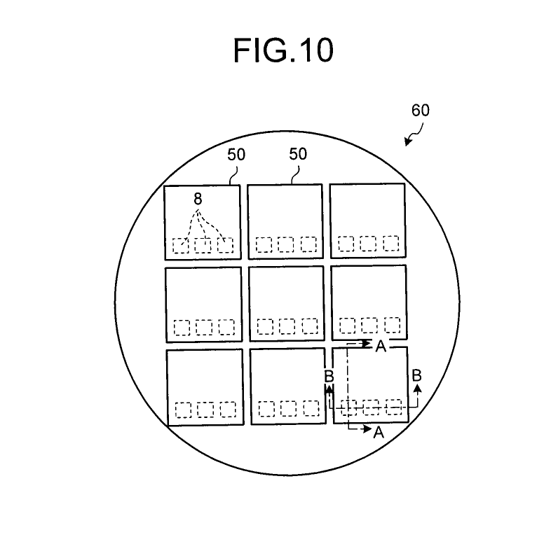

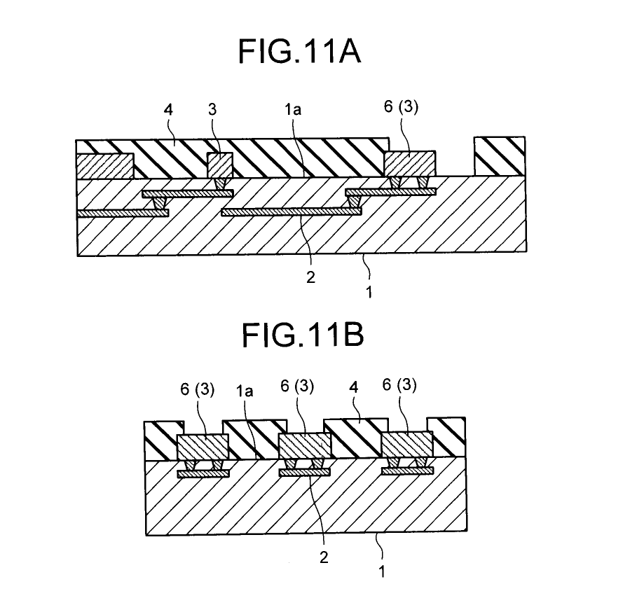

Next, a procedure of manufacturing the semiconductor devices 50 according to the first embodiment is described. FIG. 10 is a plan view of a semiconductor wafer before the semiconductor devices 50 are divided into chips. FIGS. 11A to 14A are sectional views along the arrow A-A illustrated in FIG. 10 for describing the procedure of manufacturing the semiconductor devices 50. FIGS. 11B to 14B are sectional views along the arrow B-B illustrated in FIG. 10 for describing the procedure of manufacturing the semiconductor devices 50.

The semiconductor devices 50 are obtained by dividing one semiconductor wafer 60 provided with plural semiconductor devices 50 as depicted in FIG. 10 into chips.

First, the external wires 3 including the pad electrodes 6 on the silicon substrate 1 provided with the internal wire layers 2 are formed, and then the insulation layer 4 is formed covering the pad electrodes 6. The pad electrodes 6 are electrically connected to the internal wire layers 2. Then, the insulation layer 4 is partly etched so that the pad electrodes 6 are partly exposed (see FIGS. 11A and 11B).

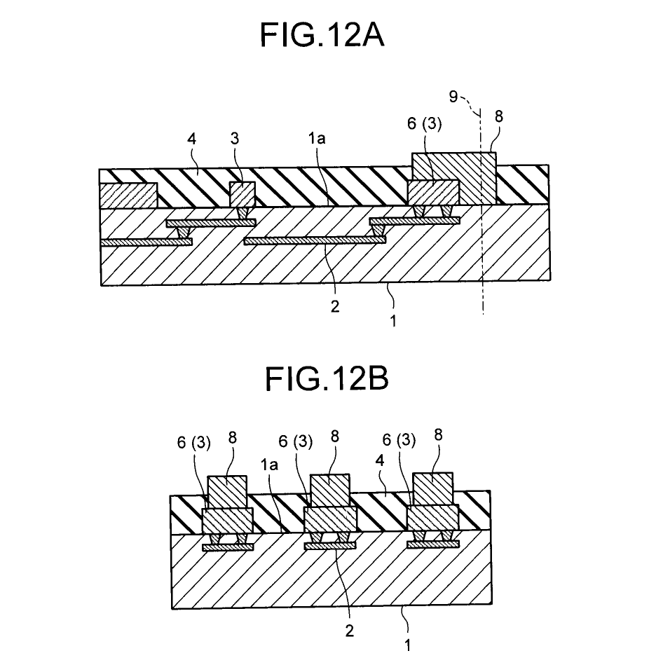

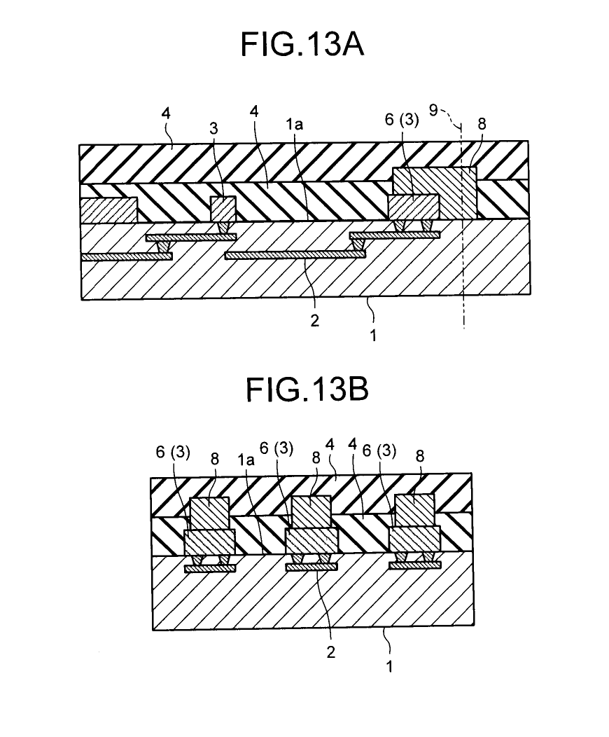

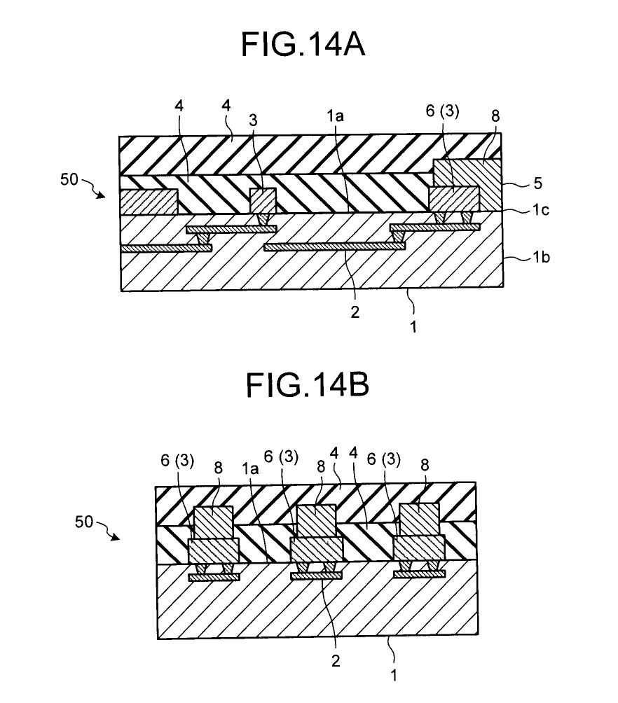

Next, a plated part 8 is formed by plating the etched part of the insulation layer 4 with metal (see FIGS. 12A and 12B). Next, the insulation layer 4 is formed further to cover the plated part 8, thereby providing the semiconductor wafer 60 (see FIGS. 13A and 13B). Then, the semiconductor wafer 60 is diced along a dicing line 9, thereby providing the semiconductor devices 50 divided as chips (see FIGS. 14A and 14B). By overlapping the dicing line 9 on the plated part 8, the plated part 8 is exposed from a side surface of the semiconductor device 50, and this will serve as the chip-side connection terminal 5.

Note that a test of the semiconductor device 50 is preferably conducted through the plated part 8 in a state that the plated part 8 is exposed at the insulation layer 4 of the semiconductor device 50 as depicted in FIGS. 12A and 12B. In the semiconductor devices 50 divided into chips as depicted in FIGS. 14A and 14B, the side surface (second surface 1b) is small in area; therefore, the chip-side connection terminal 5 to be exposed therefrom is also small. Accordingly, it may be difficult to secure the conduction through the chip-side connection terminal 5 for the test. Meanwhile, the surface of the semiconductor device 50 on the insulation layer 4 side (first surface 1a side) is larger than the side surface; therefore, the insulation layer 4 side of the semiconductor device 50 can easily expose the plated part 8 largely, so that the conduction for the test can be easily secured.

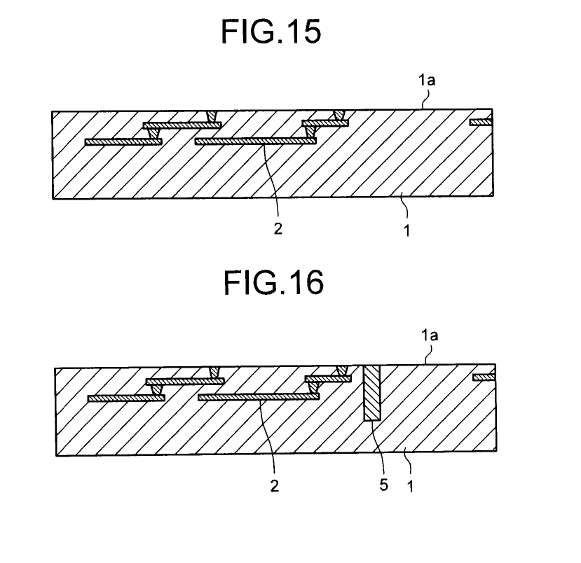

Next, another procedure of manufacturing the semiconductor devices 50 is described. FIGS. 15 to 21 are sectional views for describing another procedure of manufacturing the semiconductor devices 50. First, the silicon substrate 1 (see FIG. 15) provided with the internal wire layer 2 is partly etched, and the etched part is filled with a metal material (see FIG. 16). This filled metal material will be exposed from the side surface finally and serve as the chip-side connection terminal 5.

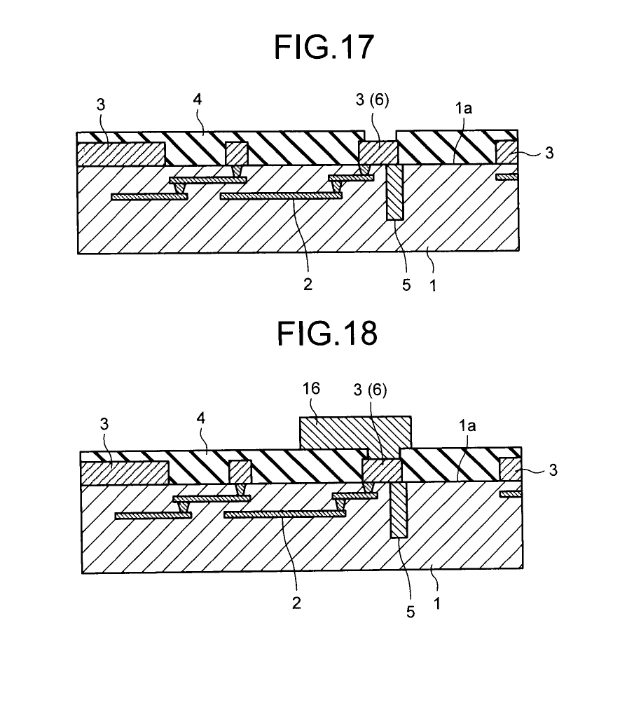

Next, the external wire 3 including the pad electrode 6 is formed so as to be electrically connected to the internal wire layer 2 and the insulation layer 4 is formed so as to cover the pad electrode 6. Then, the insulation layer 4 is partly etched so that the pad electrode 6 is partly exposed (see FIG. 17). Then, a test electrode 16 is formed on the exposed pad electrode 6 (see FIG. 18). FIG. 22 is a plan view of the semiconductor wafer 60 provided with the test electrodes 16. For the test electrode 16, for example, a coating electrode obtained by curing a coating of molten metal dissolved in an organic solvent may be used.

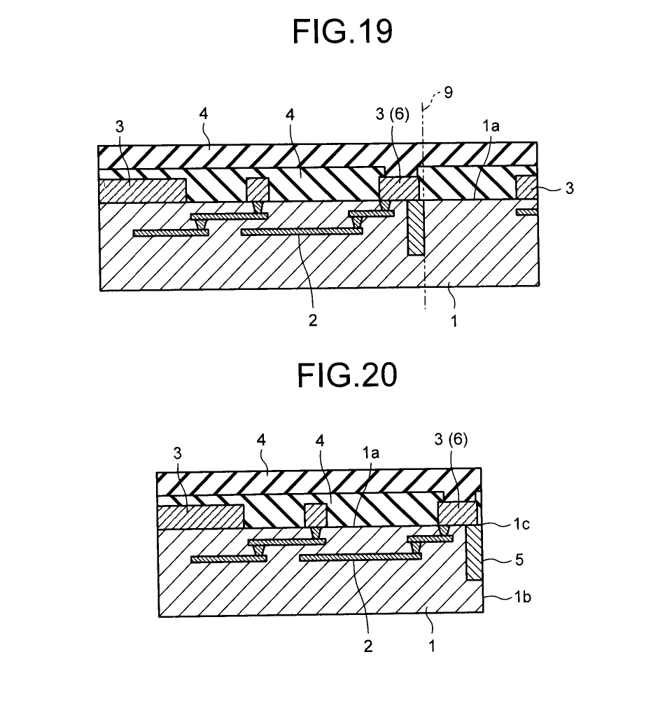

In this state, the test of the semiconductor devices 50 through the test electrodes 16 is conducted. Next, the test electrodes 16 are removed and the insulation layer 4 is formed further (see FIG. 19). For example, the test electrodes 16 are removed by melting the test electrodes 16 by a solvent.

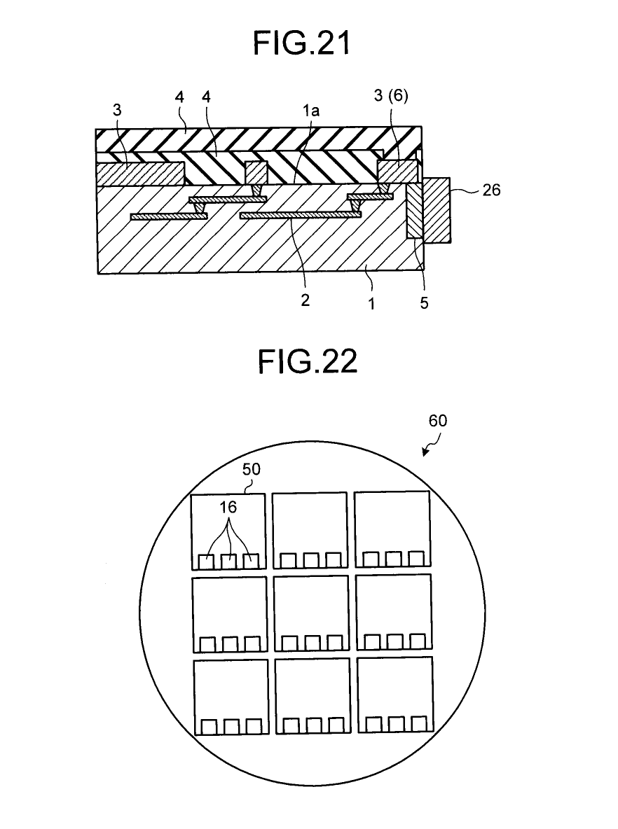

Next, the semiconductor wafer 60 is diced along the dicing line 9, thereby providing the semiconductor devices 50 divided into chips (see FIG. 20). Here, by overlapping the dicing line 9 on the chip-side connection terminal 5, the chip-side connection terminal 5 can be exposed from the side surface of the semiconductor device 50. Next, a solder 26 is formed on the chip-side connection terminal 5 (see FIG. 21).

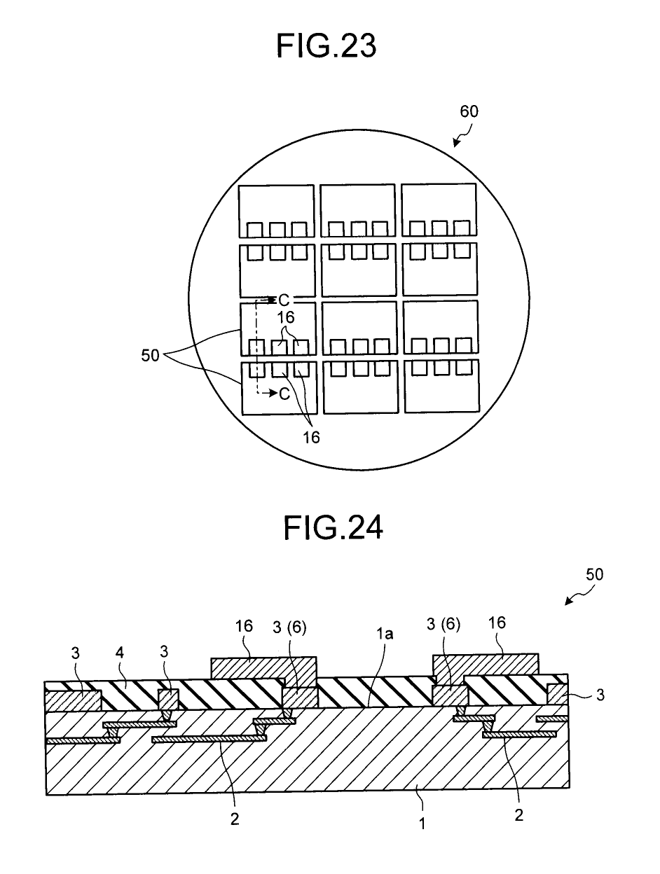

Next, another procedure of manufacturing the semiconductor devices 50 is described. FIG. 23 is a plan view of the semiconductor wafer 60 in a state that the test electrodes 16 are formed. As depicted in FIG. 23, the semiconductor wafer 60 may be manufactured so that the electrodes of the semiconductor device 50 face each other. FIG. 24 is a sectional view along the arrow C-C illustrated in FIG. 23. In this manner, the formation of the insulation layer 4, the position of the dicing line 9, etc. are similar to those in the procedure described with reference to FIGS. 15 to 22 except that the test electrodes 16 are also formed to face each other.

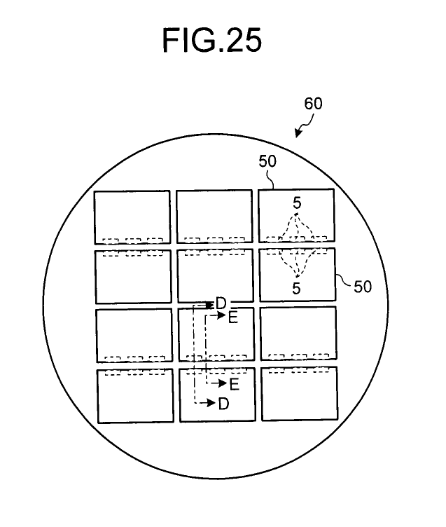

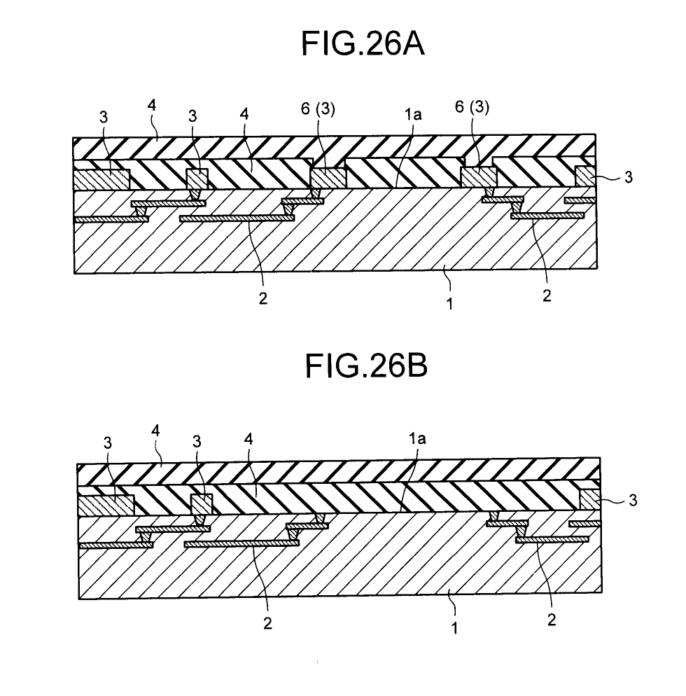

Next, another example of the procedure of manufacturing the semiconductor wafer 60 so that the electrodes of the semiconductor devices 50 face each other is described. FIG. 25 is a plan view of the semiconductor wafer 60. FIGS. 26A to 30A are sectional views taken along the line D-D illustrated in FIG. 25. FIGS. 26B to 30B are sectional views taken along the arrow E-E illustrated in FIG. 25.

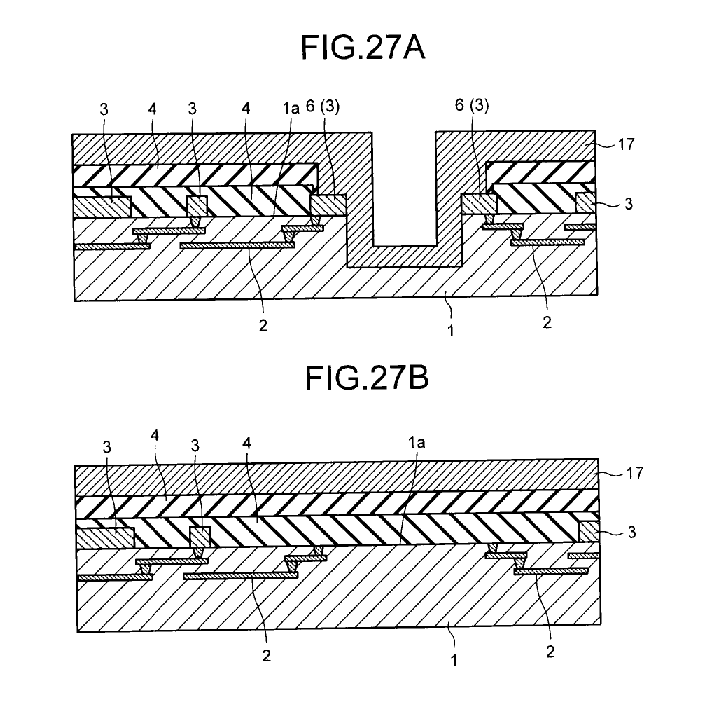

First, the pad electrodes 6 are formed on the silicon substrate 1 provided with the internal wire layers 2. Then, the insulation layer 4 is formed so as to cover the pad electrodes 6. Then, the insulation layer 4 is partly etched so that the pad electrodes 6 are partly exposed, and the insulation layer 4 is further formed (see FIGS. 26A and 26B). Next, the insulation layer 4 and the silicon substrate 1 between the pad electrodes 6 facing each other are etched. Then, a surface of the etched part is plated with metal, thereby forming a plated part 17 (see FIGS. 27A and 27B).

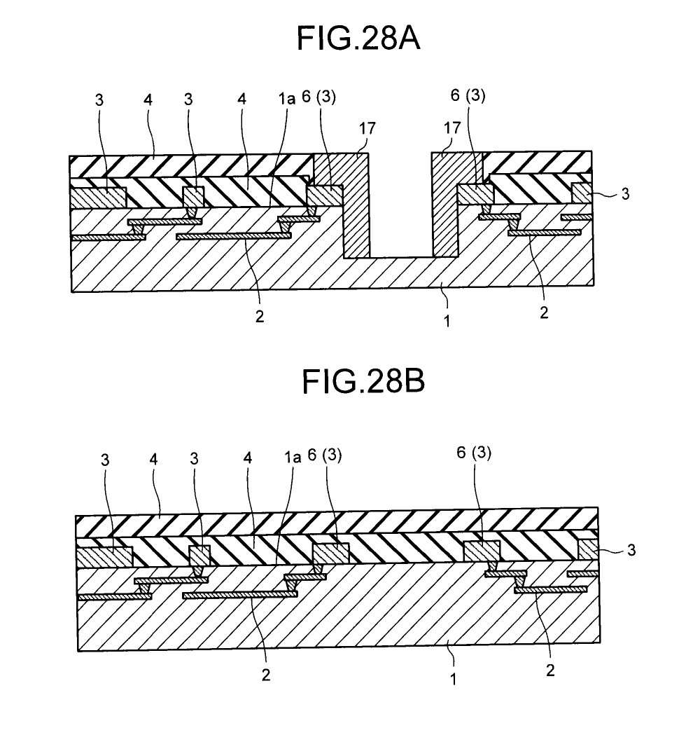

Next, the plated part 17 is etched (see FIGS. 28A and 28B). Through the plated part 17 remaining after the etching, the test of the semiconductor device 50 is conducted. In other words, the plated part 17 remaining after the etching functions as the test electrode.

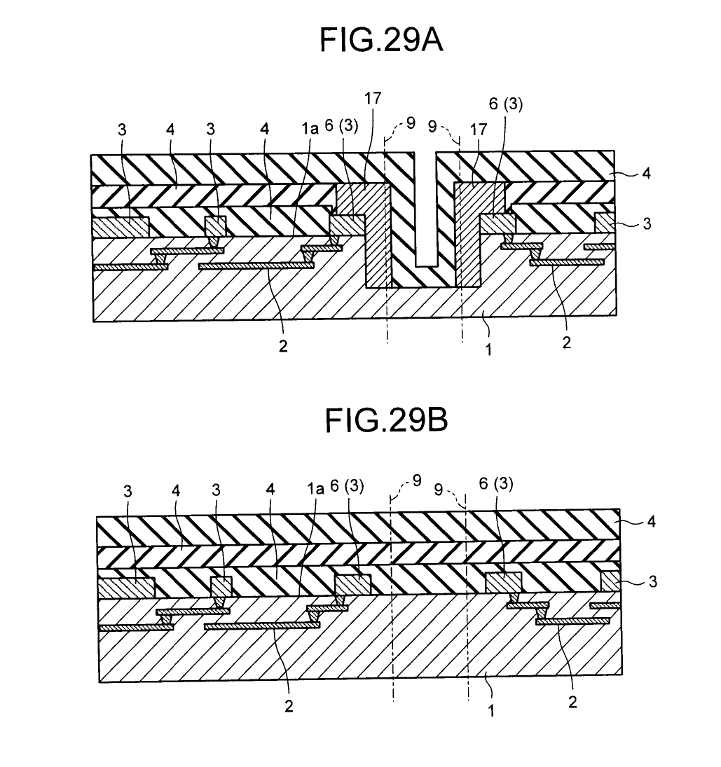

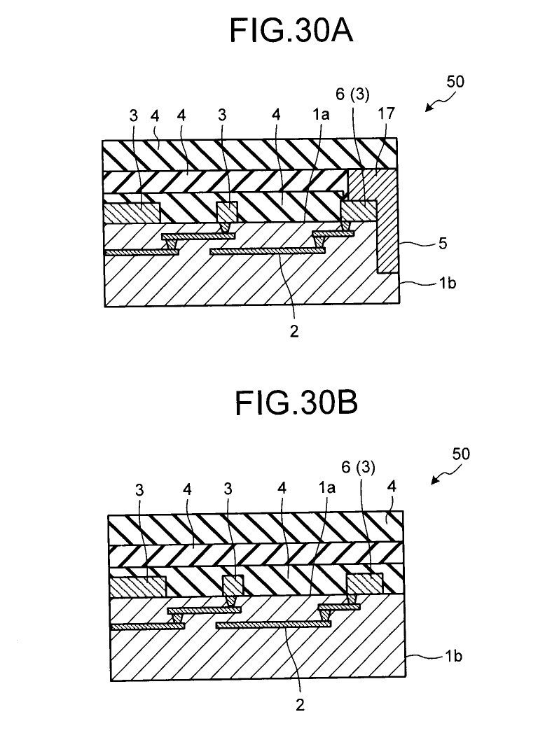

Next, the insulation layer 4 is formed further (see FIGS. 29A and 29B) and dicing is performed along the dicing line 9, thereby dividing the semiconductor devices 50 into chips (see FIGS. 30A and 30B). By overlapping the dicing line 9 on the plated part 17, the plated part 17 is exposed from the side surface of the semiconductor device 50 and this will serve as the chip-side connection terminal 5. Note that when grinding is performed from the insulation layer 4 side in this state or the state prior to the division into chips to expose the plated part 17, the semiconductor devices 51 depicted in FIG. 3 can be obtained. In this case, the insulation layer 4 is ground to expose the plated part from the first surface 1a side, and with this plated part used as the test electrode, the semiconductor device 51 can be tested.

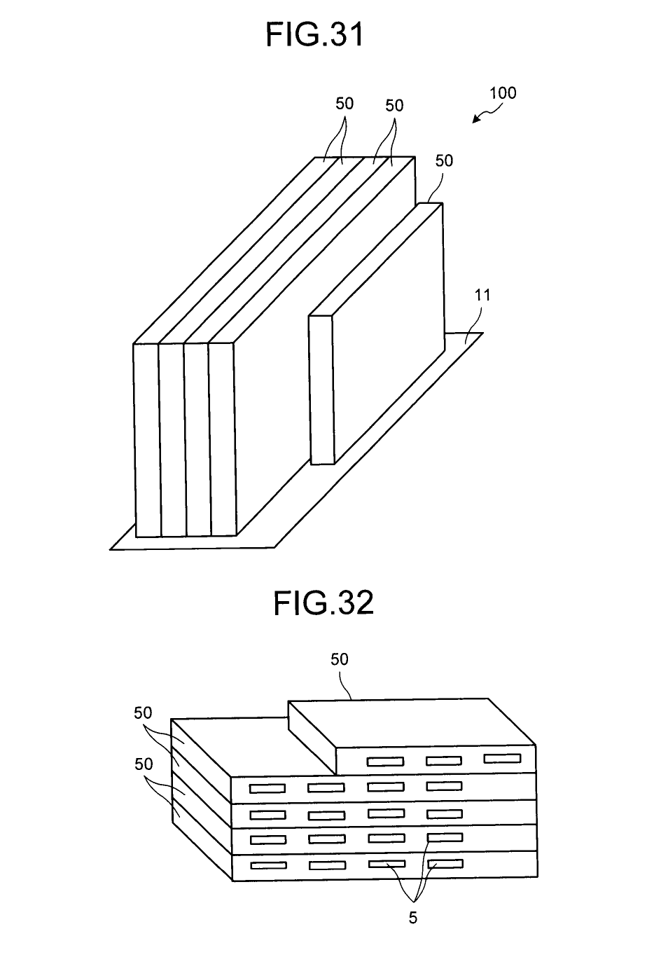

FIG. 31 is a diagram depicting another configuration example of the semiconductor module 100. FIG. 32 is a diagram in which the semiconductor device 50 included in the semiconductor module 100 depicted in FIG. 31 is seen from the chip-side connection terminal 5 side. As depicted in FIG. 31, the semiconductor devices 50 with various sizes may be arranged to form the semiconductor module 100. Here, when the chip-side connection terminals 5 arranged in a direction where the semiconductor devices 50 are arranged have the functions aligned, the printed board 11 provided with the belt-like surface electrodes 13 as depicted in FIG. 6A can be used.

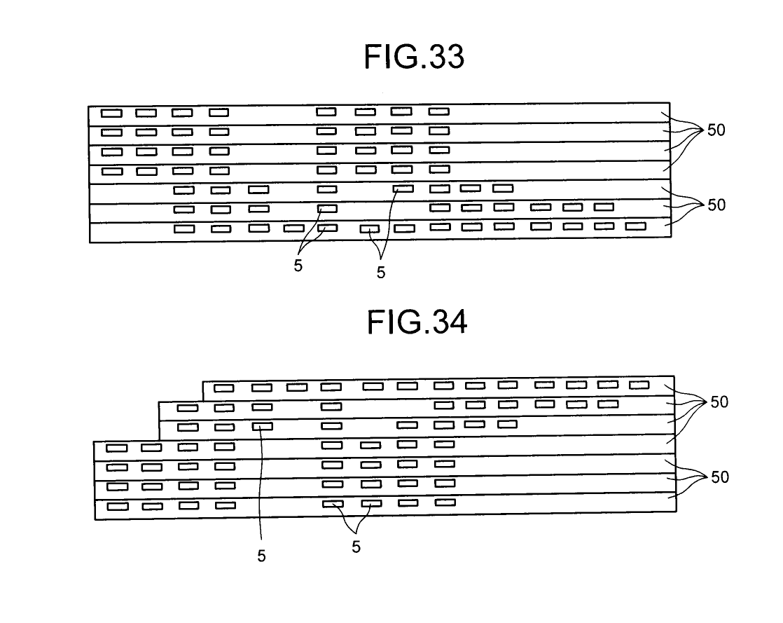

FIG. 33 is a diagram depicting another configuration example of the semiconductor devices 50 provided side by side, which is seen from the chip-side connection terminal 5 side. As depicted in FIG. 33, the semiconductor devices 50 with the chip-side connection terminals 5 arranged at various positions may be provided.

FIG. 34 is a diagram depicting another configuration example of the semiconductor devices 50 provided side by side, which is seen from the chip-side connection terminal 5 side. As depicted in FIG. 34, the semiconductor devices 50 with the chip-side connection terminals 5 having various sizes and arranged at various positions may be provided.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the sprit of the inventions. The accompanying claims and their equivalents are intended to cover such forms or modifications as would fall within the scope and spirit of the inventions.

What is claimed is:

1. A semiconductor device comprising:
a silicon substrate internally provided with a first wire layer;
an insulation film stacked on a first surface of surfaces of the silicon substrate, the first surface being approximately parallel to the first wire layer; and
a plurality of chip-side connection terminals electrically connected to the wire layer and exposed on a second surface side, the second surface being continuous from the first surface in an approximately perpendicular manner.

2. The semiconductor device according to claim 1, wherein the connection terminals are also exposed at a surface of the insulation film, the surface being parallel to the first surface.

3. The semiconductor device according to claim 1, wherein a solder is formed on the chip-side connection terminals exposed through the second surface.

4. The semiconductor device according to claim 1, wherein:
the chip-side connection terminals are arranged side by side in parallel to a boundary side serving as a boundary between the first surface and the second surface;
the chip-side connection terminals include a plurality of enable terminals; and
the enable terminals are disposed at a central part of the chip-side connection terminals arranged side by side.

5. The semiconductor device according to claim 4, wherein the enable terminals include a chip enable terminal, a write enable terminal, and an output enable terminal.

6. The semiconductor device according to claim 4, wherein:
the chip-side connection terminals include address terminals; and
the address terminals are disposed on both sides of the enable terminals.

7. The semiconductor device according to claim 1, wherein:
the chip-side connection terminals include an even number of power source terminals; and
the power source terminals are disposed symmetrically about a central line which is perpendicular to the first surface through the boundary side.

8. A semiconductor module comprising:
a plurality of semiconductor devices each including:
a silicon substrate internally provided with a first wire layer;
an insulation film stacked on a first surface of surfaces of the silicon substrate, the first surface being approximately parallel to the first wire layer; and
a plurality of chip-side connection terminals electrically connected to the wire layer and exposed on a second surface side, the second surface being continuous from the first surface in an approximately perpendicular manner; and
a wiring board internally provided with a second wire layer and having a mount surface on which the semiconductor devices are mounted and through which a substrate-side connection terminal electrically connected to the wire layer is exposed, wherein:
the semiconductor devices are mounted on the mount surface with the second surfaces facing each other; and
the semiconductor devices are arranged adjacent to each other.

9. The semiconductor module according to claim 8, wherein the connection terminals are also exposed at a surface of the insulation film, the surface being parallel to the first surface.

10. The semiconductor module according to claim 8, wherein:
the chip-side connection terminals are arranged side by side in parallel to a boundary side serving as a boundary between the first surface and the second surface;
the chip-side connection terminals include a plurality of enable terminals; and
the enable terminals are disposed at a central part of the chip-side connection terminals arranged side by side.

11. The semiconductor module according to claim 10, wherein the enable terminals include a chip enable terminal, a write enable terminal, and an output enable terminal.

12. The semiconductor module according to claim 11, wherein:
the semiconductor devices are disposed with the first surfaces facing each other; and
in the semiconductor devices disposed with the first surfaces facing each other, the chip enable terminal, the write enable terminal, and the output enable terminal are arranged point-symmetrically when seen from the second surface side.

13. The semiconductor module according to claim 10; wherein:
the chip-side connection terminals include address terminals; and
the address terminals are disposed on both sides of the enable terminals.

14. The semiconductor module according to claim 8; wherein:
the chip-side connection terminals include an even number of power source terminals; and
the power source terminals are disposed symmetrically about a central line which is perpendicular to the first surface through the boundary side.

15. The semiconductor device according to claim 8; wherein the wiring board is provided with a surrounding wall that surrounds the semiconductor devices mounted on the mount surface.

16. The semiconductor module according to claim 15, wherein the surrounding wall is higher than the semiconductor device.

17. The semiconductor module according to claim 8, further comprising another wiring board on which the wiring board is mounted.

18. A manufacturing method for a semiconductor device, in which a semiconductor wafer having a silicon substrate provided with an internal wire layer is diced along a dicing line into individual semiconductor devices, the method comprising:
forming an external wire electrically connected to the internal wire layer on the silicon substrate;
forming chip-side connection terminals electrically connected to a pad electrodes at positions on the semiconductor wafer overlapping with the dicing line; and
dicing the semiconductor wafer along the dicing line.

19. The manufacturing method for a semiconductor device according to claim 18, wherein the chip-side connection terminals are left on both sides of the dicing line by the dicing step.

20. The manufacturing method for a semiconductor device according to claim 18, wherein the chip-side connection terminals are left on one side of the dicing line by the dicing step.
